(19) United States
(12) Patent Application Publication
(10) Pub. No.: US 2026/0143775 A1
(43) Pub. Date: May 21, 2026

(54) LOW RESISTANCE PATH TO BACKSIDE METAL FEATURES

(71) Applicant: Taiwan Semiconductor Manufacturing Company, Ltd., Hsinchu (TW)

(72) Inventors: Yun-Shuo Chan, Hsinchu (TW); Shih-Chieh Wu, Hsinchu (TW); Po-Yu Huang, Hsinchu (TW); I-Wen Wu, Hsinchu City (TW); Chen-Ming Lee, Taoyuan County (TW); Mei-Yun Wang, Hsin-Chu (TW)

(21) Appl. No.: 19/074,083

(22) Filed: Mar. 7, 2025

Related U.S. Application Data
(60) Provisional application No. 63/721,247, filed on Nov. 15, 2024.

(51) Int. Cl. H10D 64/23; H01L 21/762; H01L 21/768; H10D 30/00; H10D 30/01; H10D 30/43; H10D 62/10; H10D 84/01; H10D 84/03; H10D 84/85

(52) U.S. Cl. CPC H10D 64/254; H10D 30/014; H10D 30/019; H10D 30/43; H10D 30/502; H10D 62/121; H10D 84/0186; H10D 84/038; H10D 84/851; H10W 10/014; H10W 10/17; H10W 20/083

(57) ABSTRACT

A semiconductor structure according to the present disclosure includes a semiconductor structure including a backside dielectric layer, a backside etch stop layer (ESL) over the backside dielectric layer, a first source/drain feature and a second source/drain feature over the backside ESL and spaced apart from one another along a first direction, a frontside source/drain contact disposed over the first source/drain feature and the second source/drain feature, a backside contact feature through the backside dielectric layer and the backside ESL to couple to the first source/drain feature, a through via extending through the backside dielectric layer and the backside ESL, a base fin between the backside ESL and the second source/drain feature; and an isolation feature including a portion extending along sidewalls of the base fin. The backside contact feature interfaces the through via in the backside dielectric layer and the isolation feature includes an oxide-based material.

### PRIORITY DATA

This application claims priority to U.S. Provisional Patent Application Ser. No. 63/721,247, filed Nov. 15, 2024, the entirety of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As IC devices become smaller and smaller, it is becoming more and more challenging to compactly pack frontside metal wiring without unduly increasing undesirable parasitic resistance (R) and parasitic capacitance (C). Backside metal wiring has been introduced to ease the metal wiring density over the front side of the IC devices.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 includes a flowchart of method 100A for forming a backside contact feature and a through via, according to one or more aspects of the present disclosure.

FIGS. 2-8 illustrate fragmentary cross-sectional views a precursor structure going through various steps of the method 100A in FIG. 1, according to various aspects of the present disclosure.

FIG. 9 illustrates a schematic top view of the precursor structure in FIG. 8, according to various aspects of the present disclosure.

FIG. 10 includes a flowchart of method 100B for forming a backside contact feature and a through via, according to one or more aspects of the present disclosure.

FIGS. 11-13 illustrate fragmentary cross-sectional views a precursor structure going through various steps of the method 100B in FIG. 10, according to various aspects of the present disclosure.

FIG. 14 illustrates a schematic top view of the precursor structure in FIG. 13, according to various aspects of the present disclosure.

FIG. 15 illustrates a fragmentary cross-sectional view of a semiconductor structure that includes through vias on two sides of a backside contact, according to various aspects of the present disclosure,

FIG. 16 illustrates a schematic top view of the semiconductor structure in FIG. 15, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

As integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or a portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, other nanostructures, and/or other suitable structures. The shapes of the channel region have also given a GAA transistor alternative names such as a nanosheet transistor or a nanowire transistor. As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other

Smaller device dimensions and stacking configurations put a lot of stress on frontside-only electrical routing and prompts development of device structures having routing structures below above and below a device structure. For example, backside power rails (BPR) or super power rails (SPR) have been proposed where a backside source/drain contact is formed through the substrate to come in contact with a source/drain feature and a power rail is formed on the backside of the substrate to be in contact with the backside source/drain contact. The industry continues to look for ways to reduce resistance in the routing structures, including the resistance between the frontside routing structure and backside routing structure.

The present disclosure provides methods of forming a backside contact feature and a through via abutting the backside contact feature. The through via extends between source/drain features to connect to a frontside source/drain contact. This connection provides a low-resistance conduction path between the backside contact feature and the frontside source/drain contact. In methods of the present disclosure, the opening for the through via and the opening for the backside contact feature are formed separately. A metal fill for the through via and the backside contact feature may be deposited separately or simultaneously.

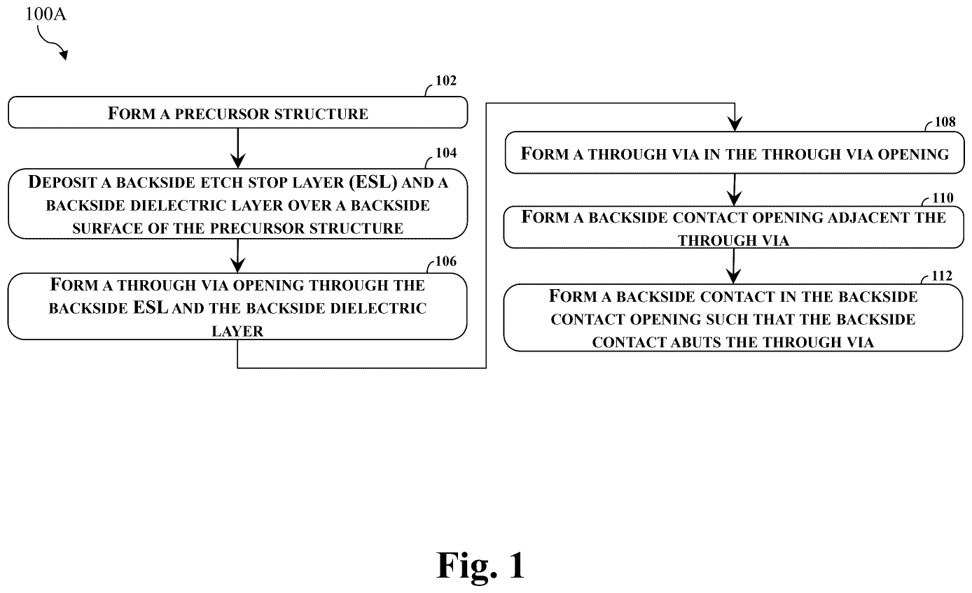

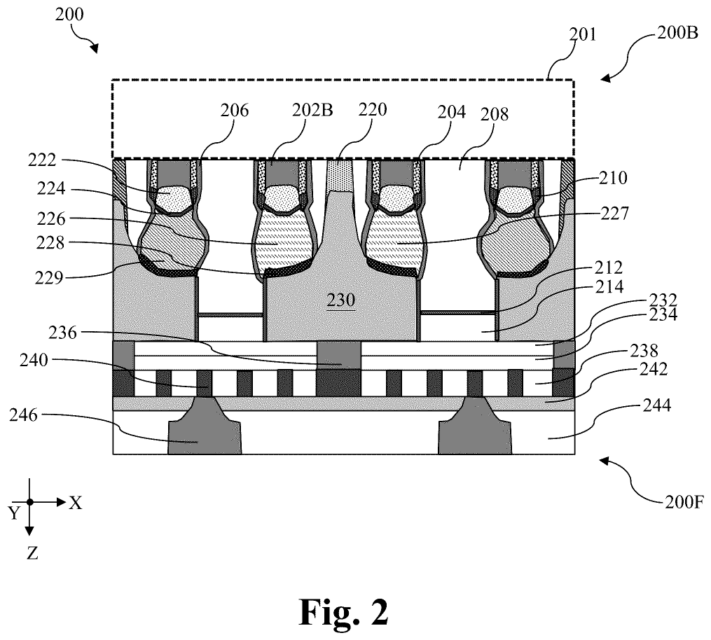

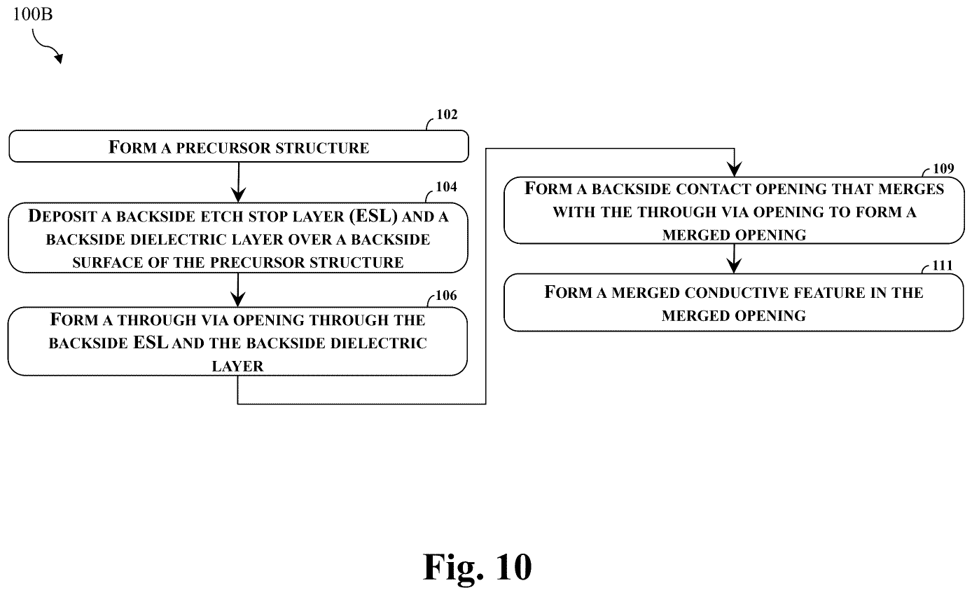

FIG. 1 and FIG. 10 are flowcharts illustrating methods 100A and 100B of forming a backside contact feature and a through via that abuts the backside contact feature. Methods 100A and 100B are merely examples and are not intended to limit the present disclosure to what is explicitly illustrated in methods 100A and 100B. Additional steps can be provided before, during and after method 100A or method 100B, and some steps described can be replaced, eliminated, or moved around for additional embodiments of the methods. Not all steps are described herein in detail for reasons of simplicity. Method 100A is described below in conjunction with FIG. 2-8, which are fragmentary cross-sectional views of a precursor structure 200 at different stages of fabrication according to various embodiments of method 100A. Method 100B is described below in conjunction with FIG. 2-4 and 11-13, which are fragmentary cross-sectional views of a precursor structure 200 at different stages of fabrication according to various embodiments of method 100B Because the precursor structure 200 will be fabricated into a semiconductor structure, the precursor structure 200 may be referred to herein as a semiconductor structure 200 as the context requires. For avoidance of doubts, the X, Y and Z directions in figures in the present disclosure are perpendicular to one another. Throughout the present disclosure, unless expressly otherwise described, like reference numerals denote like features.

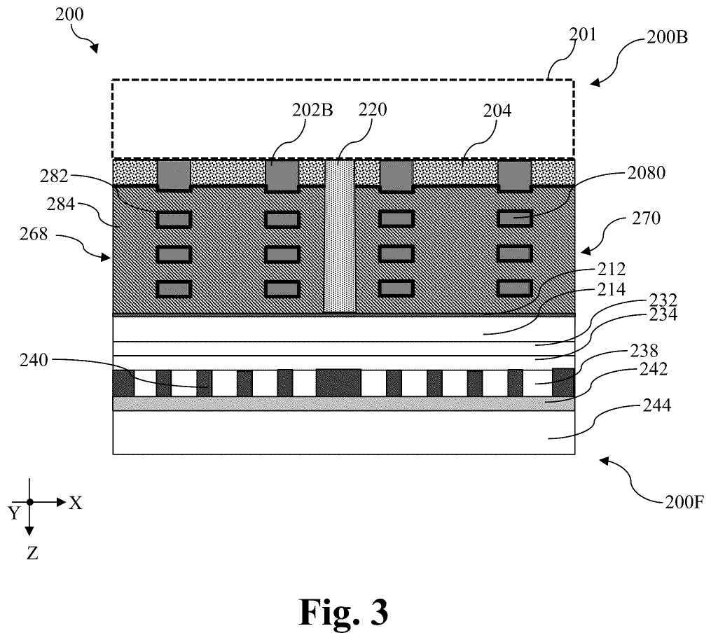

Referring to FIGS. 1, 2 and 3, method 100A includes a block 102 where a precursor structure 200 is formed. As illustrated in FIGS. 2 and 3, the precursor structure 200 includes front-end-of-line (FEOL) structures, middle-end-of-line (MEOL) structures, and frontside back-end-of-line (BEOL) structures are formed over a substrate 201 (shown in dotted lines). In one embodiment, the substrate 201 may include silicon (Si). Alternatively or additionally, the substrate 201 may include another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. Alternatively, the substrate 201 is a semiconductor-on-insulator substrate, such as a silicon-on-insulator (SOI) substrate, a silicon germanium-on-insulator (SGOI) substrate, or a germanium-on-insulator (GOI) substrate.

At block 102, an epitaxial stack having alternating semiconductor layers is formed over the substrate 201. In some instances, the epitaxial stack may include a plurality of first semiconductor layers interleaved by a plurality of second semiconductor layers. The first semiconductor layers may include silicon (Si) and the second semiconductor layers may include silicon germanium (SiGe). As shown in FIG. 3, the precursor structure 200 includes channel members 2080 released from the first semiconductor layers when the second semiconductor layers in the channel regions are selectively removed. A gate structure, such as a first gate structure 268 and a second gate structure 270 shown in FIG. 3, is formed to wrap around each of the channel members 2080. The gate structure includes a gate dielectric layer 282 and a gate electrode 284 over the gate dielectric layer 282. The gate dielectric layer 282 includes a high-k dielectric material, such as hafnium oxide (HfO), titanium oxide (TiO₂), hafnium zirconium oxide (HfZrO), tantalum oxide (Ta₂O₅), zirconium oxide (ZrO₂), lanthanum oxide (La₂O₃), yttrium oxide (Y₂O₃), or hafnium lanthanum oxide (HfLaO). In one embodiment, the gate dielectric layer 282 includes hafnium oxide. The gate electrode 284 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode 284 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

In the depicted embodiments where the transistors are GAA transistors, the epitaxial stack and a portion of the substrate 201 are patterned to form fin-shaped active regions. Each of the fin-shaped active regions may include a base fin 202B formed from the substrate 201 and a top portion formed from the epitaxial stack. An isolation feature 204 is deposited over the substrate 201 and a portion of the isolation feature 204 extends along sidewalls of the base fin 202B. The isolation feature 204 may include an oxide-based material, such as silicon oxide, silicon oxynitride, fluorine-doped silicate glass (FSG), a low-k dielectric material. As compared to the gate dielectric layer 282, the isolation feature 204 has a much smaller dielectric constant. In some instances, a dielectric constant of the gate dielectric layer 282 is at least three times of a dielectric constant of the isolation feature 204. A gate spacer 210 is formed along sidewalls of a dummy gate stack, which is later replaced with the gate structure. As shown in FIG. 2A, which is a cross-sectional view cutting across a first source/drain feature 226 and a second source/drain feature 227, a portion of the gate spacer 210 is disposed over the isolation feature 204. Referring still to FIG. 2, a buffer epitaxial layer 222 is disposed over a top surface of the base fins 202B and a bottom nitride layer 224 is disposed over the buffer epitaxial layer 222. In some embodiments, the buffer epitaxial layer 222 includes undoped silicon, undoped germanium, or undoped silicon germanium and functions to prevent leakage into the substrate 201. The bottom nitride layer 224 includes silicon nitride and functions to control growth and stress of the first source/drain feature 226 and the second source/drain feature 227. The portion of the gate spacer 210 is disposed along sidewalls of the buffer epitaxial layer 222 and the bottom nitride layer 224. In some embodiments, the gate spacer 210 may include a nitride-based material, such as silicon nitride, silicon carbonitride, or silicon oxycarbonitride.

The first source/drain feature 226 and the second source/drain feature 227 may be epitaxially grown from the exposed end walls of the channel members 2080 (shown in FIG. 3). In some embodiments, the first source/drain feature 226 and the second source/drain feature 227 may include silicon germanium (SiGe) doped with a p-type dopant, such as boron (B). In some alternative embodiments, the first source/drain feature 226 and the second source/drain feature 227 may include silicon (Si) doped with an n-type dopant, such as phosphorus (P) or arsenic (As). After the first source/drain feature 226 and the second source/drain feature 227 are formed, a contact etch stop layer (CESL) 206 is deposited over the isolation feature 204, the gate spacer 210, the first source/drain feature 226, and the second source/drain feature 227. A first interlayer dielectric (ILD) layer 208 is then formed over the CESL 206. After a planarization step, a first etch stop layer (ESL) 212 is formed over the planar top surface of the first ILD layer 208 and a second ILD layer 214 is formed over the first ESL 212. Because the first ILD layer 208 needs to accommodate the height of the source/drain features, it is thicker than the second ILD layer 214 along the Z direction. The first ILD layer 208 and the second ILD layer 214 may include an oxide-based material, such as tetraethylorthosilicate (TEOS) oxide, un-doped silicate glass, or doped silicon oxide such as borophosphosilicate glass (BPSG), fused silica glass (FSG), phosphosilicate glass (PSG), or boron doped silicon glass (BSG). The CESL 206 and the first ESL 212 may include a nitride-based material, such as silicon nitride or aluminum nitride.

The precursor 200 includes a frontside contact 230 that extends through the second ILD layer 214, the first ESL 212, and the first ILD layer 208 to electrically couple to the first source/drain feature 226 and the second source/drain feature 227 by way of a silicide feature 228. The frontside contact 230 includes a lower portion disposed between the first source/drain feature 226 and the second source/drain feature 227 and an upper portion spanning over the first source/drain feature 226 and the second source/drain feature 227. The frontside contact 230 may include cobalt (Co), nickel (Ni), ruthenium (Ru), tungsten (W), or a combination thereof. The frontside contact 230 is spaced apart from the first ILD layer 208, the first ESL 212, and the second ILD layer 214 by a barrier layer. The barrier layer may include titanium nitride or tantalum nitride. The silicide feature 228 may include titanium silicide or cobalt silicide.

A gate isolation feature 220 is formed to divide the first gate structure 268 and the second gate structure 270 as shown in FIG. 3. As shown in FIGS. 2 and 3, the gate isolation feature 220 also extends between the base fins 202B along the X direction and insulate the first gate structure 268 from the second gate structure 270. A portion of the gate isolation feature 220 extends into the isolation feature 204. While not explicitly shown in the figures, the gate isolation feature 220 may include a liner to interface the gate structures and a low-k filler spaced apart from the gate structures by the liner. In some embodiments, the liner may include an oxygen-free dielectric material such as silicon nitride and the low-k filler may include an oxide-based material.

Reference is still made to FIG. 2. The precursor structure 200 represents a structure where the frontside interconnect structure has been formed over a front side 200F of the precursor structure 200. For example, the precursor structure 200 includes a first intermetal dielectric (IMD) layer 232, a second IMD layer 234, a third IMD layer 238, a second ESL 242, and a fourth IMD layer 244 over the second ILD layer 214. In some embodiments, the second ESL 242 may have a similar composition with the first ESL 212. The first IMD layer 232, the second IMD layer 234, the third IMD layer 238, and the fourth IMD layer 244 may include an oxide-based material, such as tetraethylorthosilicate (TEOS) oxide, un-doped silicate glass, or doped silicon oxide such as borophosphosilicate glass (BPSG), fused silica glass (FSG), phosphosilicate glass (PSG), or boron doped silicon glass (BSG). First frontside metal lines 236 are disposed in the first IMD layer 232. First frontside contact vias 240 are disposed in the third IMD layer 238. Contact features 246 are disposed in the second ESL 242 and the fourth IMD layer 244. The first frontside metal lines 236, the first frontside contact vias 240, and the contact features 246 may include titanium nitride (TiN), tantalum nitride (TaN), copper (Cu), or a combination thereof. The metal nitride is the composition of the barrier layers for these conductive features.

After formation of the frontside interconnect structure, the precursor structure 200 is flipped over and the substrate 201 is thinned. A combination of grinding and planarization processes are then performed to thin down the substrate 201 to expose the isolation feature 204 and the base fins 202B. In some implementations, the thinning also exposes the gate isolation feature 220 and the first ILD layer 208.

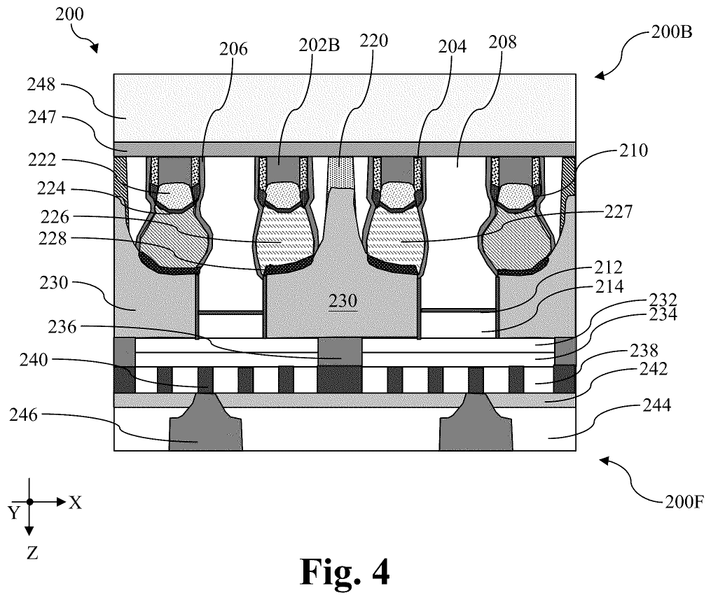

Referring to FIGS. 1 and 4, method 100A includes a block 104 where a backside etch stop layer (ESL) 247 and a backside dielectric layer 248 are deposited over a backside surface of the precursor structure 200. In some embodiments, the backside ESL 247 may include silicon nitride, silicon carbonitride, aluminum nitride, or aluminum oxide and may be deposited using chemical vapor deposition (CVD). In one embodiment, the backside ESL 247 include silicon nitride. The backside dielectric layer 248 may be deposited using CVD, flowable CVD (FCVD), or spin-on coating and may include an oxide-based dielectric material, such as tetraethylorthosilicate (TEOS) oxide, un-doped silicate glass, or doped silicon oxide such as borophosphosilicate glass (BPSG), fused silica glass (FSG), phosphosilicate glass (PSG), or boron doped silicon glass (BSG). In one embodiment, the backside dielectric layer 248 includes silicon oxide.

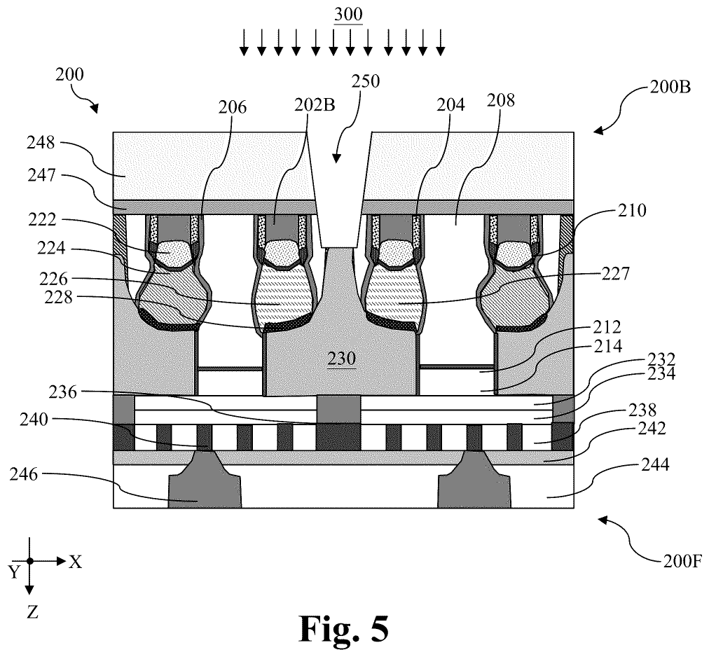

Referring to FIGS. 1 and 5, method 100A includes a block 106 where a through via opening 250 is formed through the backside ESL 247 and the backside dielectric layer 248. As shown in FIG. 5, the through via opening 250 is intended to penetrate through the backside dielectric layer 248, the backside ESL 247, the gate isolation feature 220, and the first ILD layer 208 to expose the lower portion of the frontside contact 230. As described above, the backside dielectric layer 248 and the low-k filler layer in the gate isolation feature 220 are formed of oxide-based dielectric material and the backside ESL 247 and the liner of the gate isolation feature 220 are formed of nitride-based material. Because the backside ESL 247 and the liner are thinner than the backside dielectric layer 248 and the low-k filler, the forming of the through via opening 250 primarily etches oxide-based material. Photolithography and etching processes may be used to form the through via opening 250. In an example process, a patterned mask (not explicitly shown in FIG. 5) is formed over the backside dielectric layer 248 and then a first etch process 300 is performed to etch the precursor structure 200 using the patterned mask as an etch mask. The first etch process 300 is configured to etch silicon oxide faster than it etches silicon or silicon nitride. In some embodiments, the first etch process 300 may include a dry etch process that uses a fluorine-containing gas (e.g., carbon tetrafluoride (CF₄), octafluorocyclobutane (C₄F₈), nitrogen trifluoride (NF₃), chlorine trifluoride (ClF₃), or sulfur hexafluoride (SF₆)), a chlorine-containing gas (e.g., chlorine (Cl₂)), oxygen (O₂), or hydrogen (H₂). Because the through via opening 250 has a greater dimension and does not require alignment with the source/drain features, the photolithography process required to form the through via opening 250 may include immersion lithography, which implements a deep ultraviolet (DUV) radiation source having a wavelength between about 100 nm and about 300 nm, such as 193 nm. That is, the photolithography process used to form the through via opening 250 may not involve use of extreme ultraviolet (EUV) photolithography.

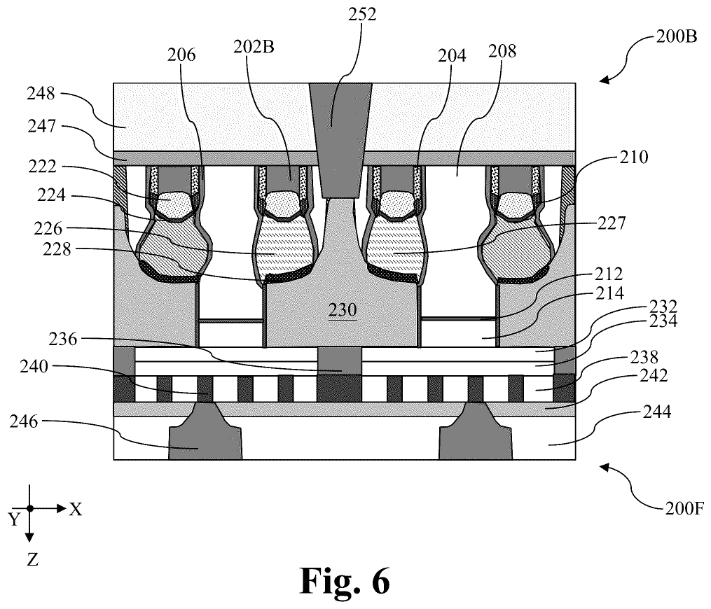

Referring to FIGS. 1 and 6, method 100A includes a block 108 where a through via 252 is formed in the through via opening 250. In some embodiments, the through via 252 may include cobalt (Co), nickel (Ni), ruthenium (Ru), tungsten (W), copper (Cu), or a combination thereof. In some embodiments, the through via 252 may be formed by depositing the foregoing metal to fill in the through via opening 250 by physical vapor deposition (PVD), metal organic CVD (MOCVD), electroplating, or electroless plating. After the deposition of the metal fill, a planarization process, such as a chemical mechanical polishing (CMP), is performed to remove excess metal over the backside dielectric layer 248 to form the through via 252.

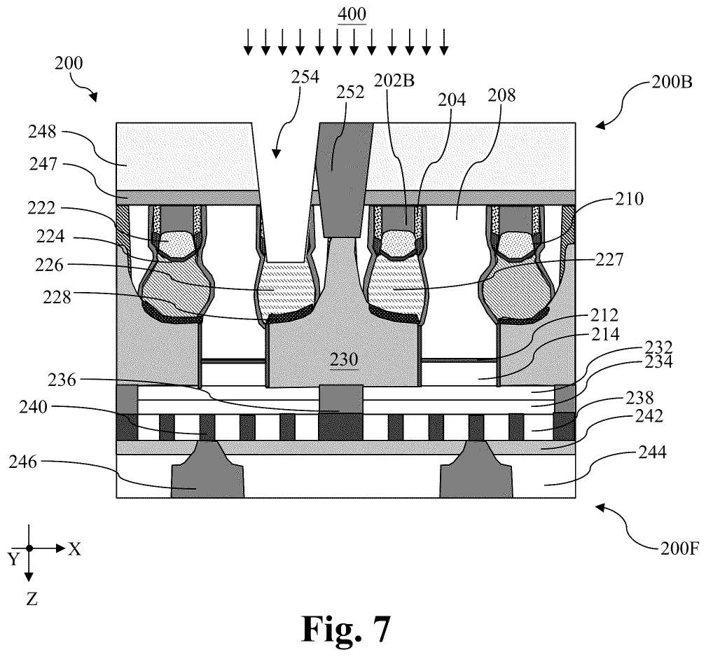

Referring to FIGS. 1 and 7, method 100A includes a block 110 where a backside contact opening 254 is formed adjacent the through via 252. As shown in FIG. 7, the backside contact opening 254 exposes the first source/drain feature 226 and is intended to penetrate through the backside dielectric layer 248, the backside ESL 247, the base fin 202B, the buffer epitaxial layer 222, and the bottom nitride layer 224 to expose a bottom surface of the first source/drain feature 226. As described above, the base fin 202B and the buffer epitaxial layer 222 are formed of semiconductor material, such as silicon or germanium. As a result, the forming of the backside contact opening 254 primarily etches semiconductor material. Photolithography and etching processes may be used to form the backside contact opening 254. In an example process, a patterned mask (not explicitly shown in FIG. 7) is formed over the backside dielectric layer 248 and then a second etch process 400 is performed to etch the precursor structure 200 using the patterned mask as an etch mask. The second etch process 400 is configured to etch silicon faster than it etches silicon oxide or silicon nitride. It is noted that the opening in the patterned mask partially overlaps the through via 252 to ensure that the to-be-formed backside contact 260 abuts and physically interfaces the through via 252. In some embodiments, the second etch process 400 may include a dry etch process that uses a fluorine-containing gas (e.g., carbon tetrafluoride (CF₄), octafluorocyclobutane (C₄F₈), nitrogen trifluoride (NF₃), chlorine trifluoride (ClF₃), or sulfur hexafluoride (SF₆)), oxygen (O₂), or hydrogen (H₂). Because the backside contact opening 254 has a smaller dimension and requires satisfactory alignment with the first source/drain feature 226, the photolithography process required to form the backside contact opening 254 may include use of extreme ultraviolet (EUV) photolithography, which implement a radiation source having a wavelength between about 10 nm and about 100 nm, such as about 13.5 nm. Because the lower portion of the frontside contact 230 extends lower than a bottom surface of the first source/drain feature 226, the backside contact opening 254 extends to a level lower than a bottom surface of the through via 252.

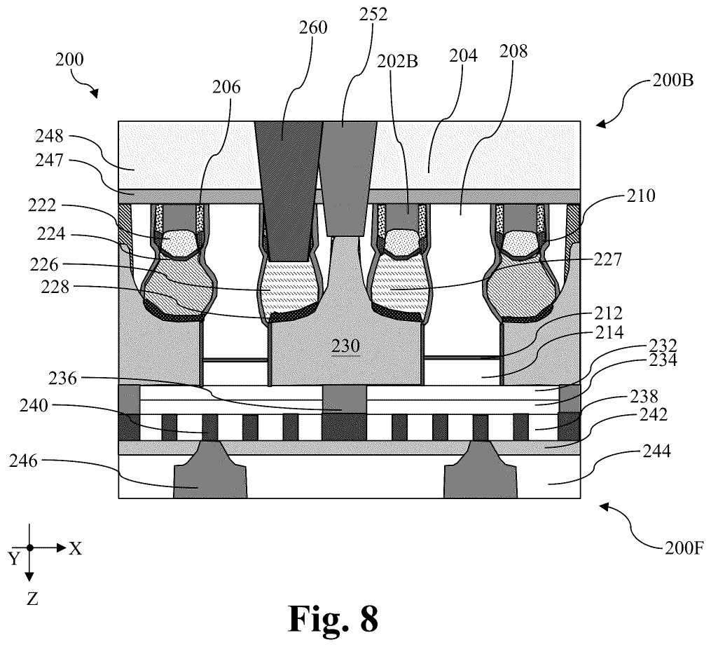

Referring to FIGS. 1 and 8, method 100A includes a block 112 where a backside contact 260 in the backside contact opening 254 such that the backside contact 260 abuts the through via 252. In some embodiments, the backside contact 260 may include cobalt (Co), nickel (Ni), ruthenium (Ru), tungsten (W), copper (Cu), or a combination thereof. In some embodiments, the backside contact 260 may be formed by depositing the foregoing metal to fill in the backside contact opening 254 by PVD, MOCVD, electroplating, or electroless plating. After the deposition of the metal fill, a planarization process, such as a chemical mechanical polishing (CMP), is performed to remove excess metal over the backside dielectric layer 248 to form the backside contact 260. As shown in FIG. 8, due to the planarization process, top surfaces (with the precursor structure 200 flipped upside down) of the backside dielectric layer 248, the backside contact 260, and the through via 252 are coplanar.

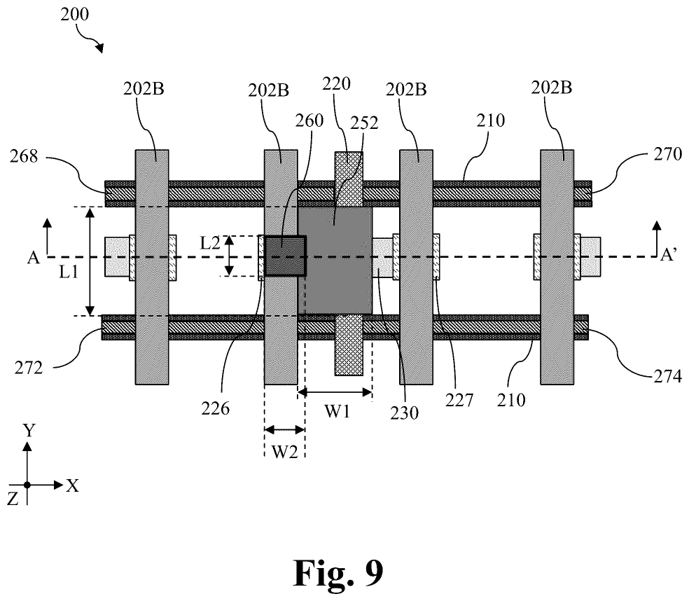

FIG. 9 illustrates a schematic top view from a back side 200B (shown in FIG. 8) of the precursor structure 200 in FIG. 8. As shown in FIG. 9, FIG. 8 represents a fragmentary cross-section through line A-A in FIG. 9. Referring to FIG. 9, the base fins 202B extend lengthwise along the Y direction and are parallel to one another. The first gate structure 268 and the second gate structure 270 extend lengthwise along the X direction. A third gate structure 272 and a fourth gate structure 274 also extend lengthwise along the X direction. The gate isolation feature 220 extends lengthwise along the Y direction between the first gate structure 268 and the second gate structure 270 as well as between the third gate structure 272 and the fourth gate structure 274. The gate isolation feature 220 isolates the first gate structure 268 from the second gate structure 270 such that isolates the first gate structure 268 and the second gate structure 270 are lengthwise aligned along the X direction. Similarly, the gate isolation feature 220 isolates the third gate structure 272 from the fourth gate structure 274 such that isolates the third gate structure 272 and the fourth gate structure 274 are lengthwise aligned along the X direction. Each of the first gate structure 268, the second gate structure 270, the third gate structure 272, and the fourth gate structure 274 wraps around each of the channel members 2080 (shown in FIG. 3) disposed over the base fins 202B. The gate spacer 210 is disposed along sidewalls of the first gate structure 268, the second gate structure 270, the third gate structure 272, and the fourth gate structure 274. As shown in FIG. 9, the gate isolation feature 220 interfaces sidewalls of the gate spacer 210 along sidewalls of the first gate structure 268, the second gate structure 270, the third gate structure 272, and the fourth gate structure 274. In some embodiments, the first etch process 300 used to form of the through via opening 250 etches the gate spacer 210 at a slower rate such that the gate spacer 210 defines the boundaries of the through via 252 along the Y direction. In some embodiments represented in FIG. 9, the through via 252 abuts and interfaces the gate spacer 210. Reference is still made to FIG. 9. The first source/drain feature 226 and the second source/drain feature 227 are each disposed over a base fin 202B. With the back side 200B facing up, the frontside contact 230 are disposed below the first source/drain feature 226 and the second source/drain feature 227 to couple to the same by way of the silicide feature 228 (not shown in FIG. 9).

In the depicted embodiments, the through via 252 includes a first width W1 along the X direction and a first length L1 along the Y direction. The first width W1 is different from the first length L1. In some implementation, the first length L1 is greater than the first width W1. In one embodiment, a ratio of the first length L1 to the first width W1 is between about 1.5 and about 2.5. In some instances, the first length L1 is between about 24 nm and about 72 nm and the first length W1 is between about 12 nm and about 36 nm. The backside contact 260 includes a second width W2 along the X direction and a second length L2 along the Y direction. The second width W2 is different from the second length L2. In some implementation, the second width W2 is greater than the second length L2 because the width of the backside contact 260 is purposely increased to overlap and interface the through via 252. In one embodiment, a ratio of the second width W2 to the second length is between about 1.1 and about 1.5. Because of the differences in the formation methods, the through via 252 has a larger footprint than the backside contact 260. That is, the first length L1 is greater than the second length L2 and the first width W1 is greater than the second width W2.

In method 100A described above, openings for the backside contact 260 and through via 252 are formed separately and the backside contact 260 and through via 252 are formed in the respectively openings separately. In method 100B, openings for the backside contact 260 and through via 252 are formed separately but the backside contact 260 and through via 252 are formed simultaneously.

Referring to FIGS. 10, 2 and 3, method 100B includes a block 102 where a precursor structure 200 is formed. Operations at block 102 have been described in detail above in association with method 100A. A detailed description of block 102 is omitted here for brevity.

Referring to FIGS. 10 and 4, method 100A includes a block 104 where a backside etch stop layer (ESL) 247 and a backside dielectric layer 248 are deposited over a backside surface of the precursor structure 200. Operations at block 104 have been described in detail above in association with method 100A. A detailed description of block 104 is omitted here for brevity.

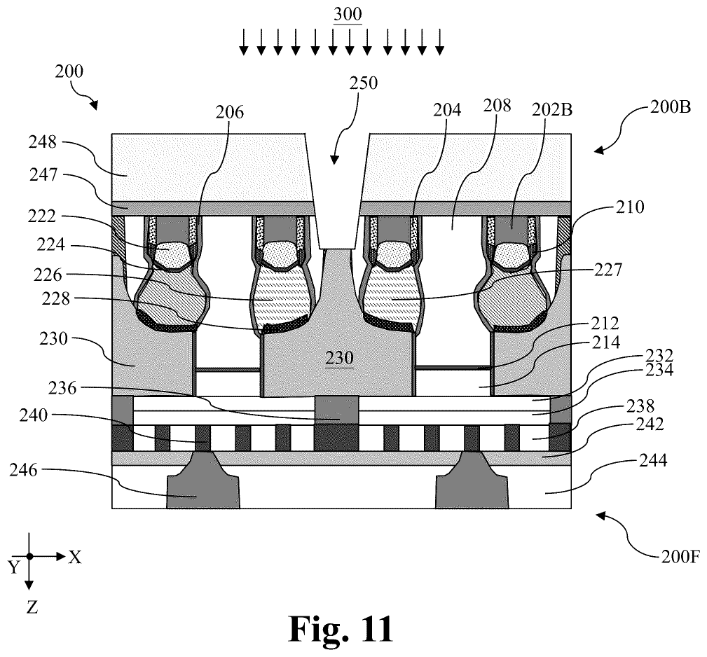

Referring to FIGS. 10 and 11, method 100A includes a block 106 where a through via opening 250 is formed through the backside ESL 247 and the backside dielectric layer 248. As shown in FIG. 11, the through via opening 250 is intended to penetrate through the backside dielectric layer 248, the backside ESL 247, the gate isolation feature 220, and the first ILD layer 208 to expose the lower portion of the frontside contact 230. As described above, the backside dielectric layer 248 and the low-k filler layer in the gate isolation feature 220 are formed of oxide-based dielectric material and the backside ESL 247 and the liner of the gate isolation feature 220 are formed of nitride-based material. Because the backside ESL 247 and the liner are thinner than the backside dielectric layer 248 and the low-k filler, the forming of the through via opening 250 primarily etches oxide-based material. Photolithography and etching processes may be used to form the through via opening 250. In an example process, a patterned mask (not explicitly shown in FIG. 11) is formed over the backside dielectric layer 248 and then the first etch process 300 is performed to etch the precursor structure 200 using the patterned mask as an etch mask. In some embodiments, the first etch process 300 may include a dry etch process that uses a fluorine-containing gas (e.g., carbon tetrafluoride (CF₄), octafluorocyclobutane (C₄F₈), nitrogen trifluoride (NF₃), chlorine trifluoride (ClF₃), or sulfur hexafluoride (SF₆)), a chlorine-containing gas (e.g., chlorine (Cl₂)), oxygen (O₂), or hydrogen (H₂). Because the through via opening 250 has a greater dimension and does not require alignment with the source/drain features, the photolithography process required to form the through via opening 250 may include immersion lithography, which implements a deep ultraviolet (DUV) radiation source having a wavelength between about 100 nm and about 300 nm, such as 193 nm. That is, the photolithography process used to form the through via opening 250 may not involve use of extreme ultraviolet (EUV) photolithography.

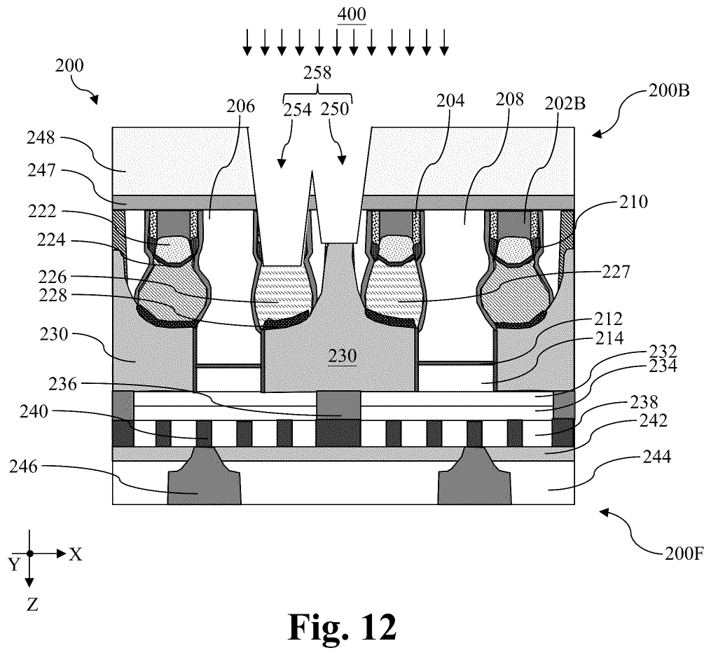

Referring to FIGS. 10 and 12, method 100A includes a block 109 where a backside contact opening 254 that merges with the through via opening 250 is formed. The backside contact opening 254 exposes the first source/drain feature 226 and is intended to penetrate through the backside dielectric layer 248, the backside ESL 247, the base fin 202B, the buffer epitaxial layer 222, and the bottom nitride layer 224 to expose a bottom surface of the first source/drain feature 226. The base fin 202B and the buffer epitaxial layer 222 are formed of semiconductor material, such as silicon or germanium. As a result, the forming of the backside contact opening 254 primarily etches semiconductor material. Photolithography and etching processes may be used to form the backside contact opening 254. Because the backside contact opening 254 is formed while the through via opening 250 is not filled by any metal fill, a bottom antireflective coating (BARC) layer may be deposited to temporarily fill the through via opening 250. A patterned mask (not explicitly shown in FIG. 12) is then formed over the backside dielectric layer 248 and then a second etch process 400 is performed to etch the precursor structure 200 using the patterned mask as an etch mask. It is noted that the opening in the patterned mask partially overlaps the through via opening 250 to ensure that backside contact opening 254 and the through via opening 250 are in fluid communication with one another. In some embodiments, the dielectric dividing structure between the through via opening 250 and the backside contact opening 254 is lower than a top surface of the backside dielectric layer 248. For ease of reference, the merged backside contact opening 254 and the through via opening 250 shown in FIG. 12 may be referred to as a merged opening 258. In some embodiments, the second etch process 400 may include a dry etch process that uses a fluorine-containing gas (e.g., carbon tetrafluoride (CF₄), octafluorocyclobutane (C₄F₈), nitrogen trifluoride (NF₃), chlorine trifluoride (ClF₃), or sulfur hexafluoride (SF₆)), oxygen (O₂), or hydrogen (H₂). Because the backside contact opening 254 has a smaller dimension and requires satisfactory alignment with the first source/drain feature 226, the photolithography process required to form the backside contact opening 254 may include use of extreme ultraviolet (EUV) photolithography, which implement a radiation source having a wavelength between about 10 nm and about 100 nm, such as about 13.5 nm. Because the lower portion of the frontside contact 230 extends lower than a bottom surface of the first source/drain feature 226, the backside contact opening 254 extends to a level lower than a bottom surface of the through via 252.

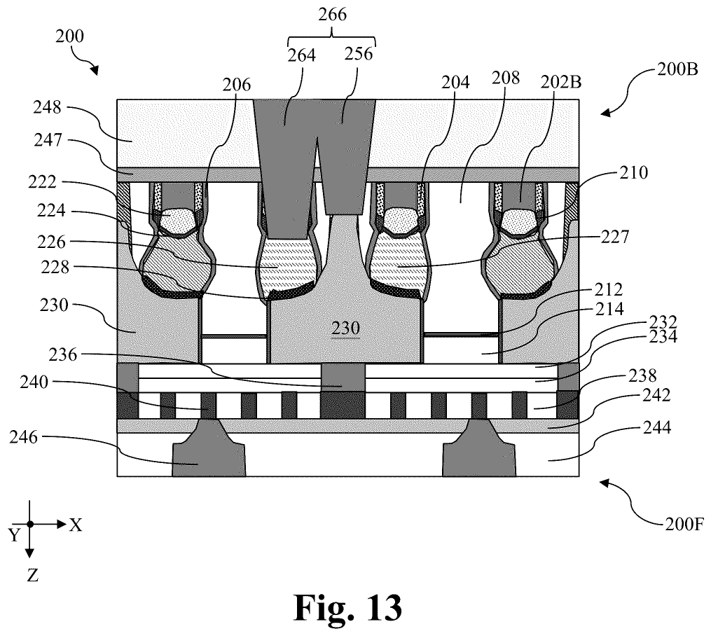

Referring to FIGS. 10 and 13, method 100A includes a block 111 where a merged conductive feature 266 is formed in the merged opening 258. In some embodiments, the merged conductive feature 266 may include cobalt (Co), nickel (Ni), ruthenium (Ru), tungsten (W), copper (Cu), or a combination thereof. In some embodiments, the backside contact 260 may be formed by depositing the foregoing metal to fill in the merged opening 258 by PVD, MOCVD, electroplating, or electroless plating. After the deposition of the metal fill, a planarization process, such as a chemical mechanical polishing (CMP), is performed to remove excess metal over the backside dielectric layer 248 to form the merged conductive feature 266. As shown in FIG. 13, due to the planarization process, top surfaces (with the precursor structure 200 flipped upside down) of the backside dielectric layer 248 and the merged conductive feature 266 are coplanar. As the merged opening 258 includes the backside contact opening 254 and the through via opening 250, the merged conductive feature 266 includes a through via leg 256 in the through via opening 250 and a backside contact leg 264 in the backside contact opening 254. The through via leg 256 and the backside contact leg 264 partially merge in the backside dielectric layer 248 and bifurcate as they extend toward the first source/drain feature 226 and the frontside contact 230.

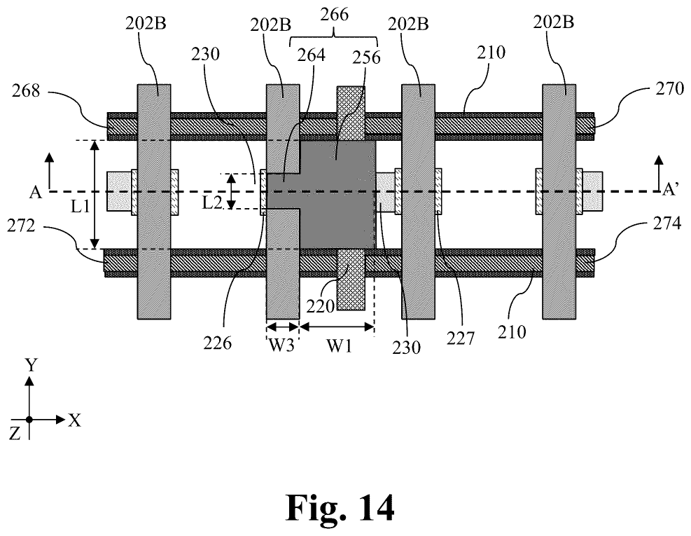

FIG. 14 illustrates a schematic top view from a back side 200B (shown in FIG. 13) of the precursor structure 200 in FIG. 13. Referring to FIG. 14, the base fins 202B extend lengthwise along the Y direction and are parallel to one another. The first gate structure 268 and the second gate structure 270 extend lengthwise along the X direction. The third gate structure 272 and the fourth gate structure 274 also extend lengthwise along the X direction. The gate isolation feature 220 extends lengthwise along the Y direction between the first gate structure 268 and the second gate structure 270 as well as between the third gate structure 272 and the fourth gate structure 274. The gate isolation feature 220 isolates the first gate structure 268 from the second gate structure 270 such that isolates the first gate structure 268 and the second gate structure 270 are lengthwise aligned along the X direction. Similarly, the gate isolation feature 220 isolates the third gate structure 272 from the fourth gate structure 274 such that isolates the third gate structure 272 and the fourth gate structure 274 are lengthwise aligned along the X direction. Each of the first gate structure 268, the second gate structure 270, the third gate structure 272, and the fourth gate structure 274 wraps around each of the channel members 2080 (shown in FIG. 3) disposed over the base fins 202B. The gate spacer 210 is disposed along sidewalls of the first gate structure 268, the second gate structure 270, the third gate structure 272, and the fourth gate structure 274. As shown in FIG. 14, the gate isolation feature 220 interfaces sidewalls of the gate spacer 210 along sidewalls of the first gate structure 268, the second gate structure 270, the third gate structure 272, and the fourth gate structure 274. In some embodiments, the first etch process 300 used to form of the through via opening 250 etches the gate spacer 210 at a slower rate such that the gate spacer 210 defines the boundaries of the through via leg 256 along the Y direction. In some embodiments represented in FIG. 14, the through via leg 256 of the merged conductive feature 266 abuts and interfaces the gate spacer 210. Reference is still made to FIG. 14. The first source/drain feature 226 and the second source/drain feature 227 are each disposed over a base fin 202B. With the back side 200B (shown in FIG. 13) facing up, the frontside contact 230 are disposed below the first source/drain feature 226 and the second source/drain feature 227 to couple to the same by way of the silicide feature 228 (not shown in FIG. 13).

In the depicted embodiments, the through via leg 256 and the backside contact leg 264 of the merged conductive feature 266 form a shape like a letter “T” or a T-shape in a top view. The through via leg 256 includes a first width W1 along the X direction and a first length L1 along the Y direction. The first width W1 is different from the first length L1. In some implementation, the first length L1 is greater than the first width W1. In one embodiment, a ratio of the first length L1 to the first width W1 is between about 1.5 and about 2.5. In some instances, the first length L1 is between about 24 nm and about 72 nm and the first length W1 is between about 12 nm and about 36 nm. The backside contact leg 264 includes a third width W3 along the X direction and a second length L2 along the Y direction. The second length L2 may be similar to the third width W3. In one embodiment, a ratio of the second width W2 to the second length is between about 0.9 and about 1.1. Because of the differences in the formation methods, the through via leg 256 has a larger footprint than the backside contact leg 264. That is, the first length L1 is greater than the second length L2 and the first width W1 is greater than the third width W3. The through via leg 256 and the backside contact leg 264 are continuous without any interface because they are formed simultaneously. The same cannot be said for the backside contact 260 and the through via 252. Because the backside contact 260 and the through via 252 are formed separately, an observable interface exists between the backside contact 260 and the through via 252.

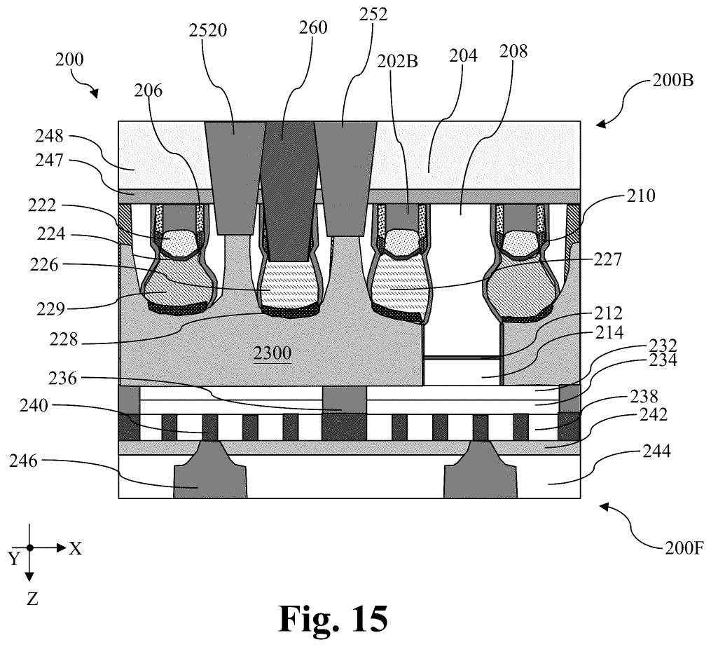

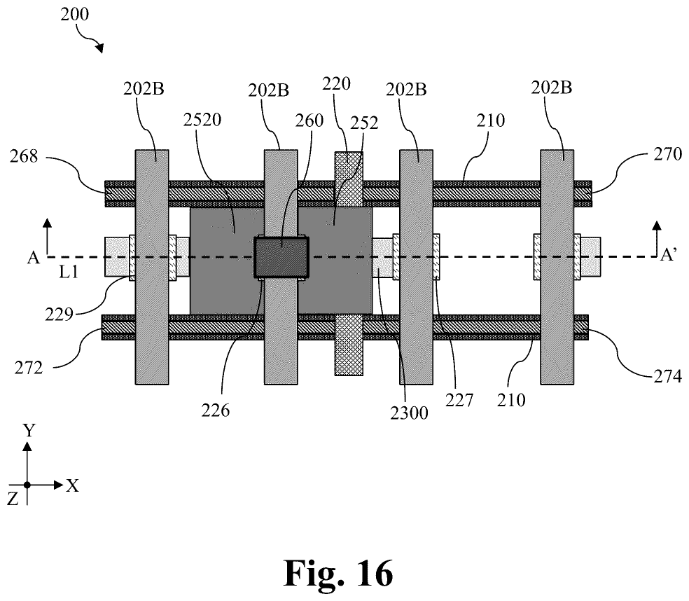

In the precursor structure 200 shown in FIG. 2, the frontside contact 230 does not extend over a third source/drain feature 229. In some alternative embodiment illustrated in FIG. 15, a long frontside contact 2300 continuously extend over the first source/drain feature 226, the second source/drain feature 227, and the third source/drain feature 229 and interface them by way of the silicide feature 228. This arrangement allows the possibility for forming another through via 2520 to interface the long frontside contact 2300. In some embodiments, the composition and formation method of the through vias 252 and 2520 are similar. In the depicted alternative embodiment, the through vias 252 and 2520 sandwich and partially overlap with the backside contact 260. The addition of the through via 2520 may further reduce the contact resistance. FIG. 16 schematically illustrates a top view of the semiconductor structure 200 in FIG. 15. As shown in FIG. 16, FIG. 15 represents a fragmentary cross-section through line A-A in FIG. 16. Through vias 252 and 2520 may appear symmetrical with respect to the backside contact 260. Both the through vias 252 and 2520 interface the gate spacer 210 along the lengthwise direction (i.e., Y direction).

In one example aspect, the present disclosure provides a semiconductor structure. The semiconductor structure includes a backside dielectric layer, a backside etch stop layer (ESL) over the backside dielectric layer, a first source/drain feature and a second source/drain feature over the backside ESL and spaced apart from one another along a first direction, a frontside source/drain contact disposed over the first source/drain feature and the second source/drain feature, a backside contact feature extending through the backside dielectric layer and the backside ESL to couple to the first source/drain feature, a through via extending through the backside dielectric layer and the backside ESL to couple to the frontside source/drain contact, a base fin between the backside ESL and the second source/drain feature, and an isolation feature including a portion extending along sidewalls of the base fin. The backside contact feature interfaces the through via in the backside dielectric layer and the isolation feature includes an oxide-based material.

In some embodiments, the frontside source/drain contact includes a portion that extends between the first source/drain feature and the second source/drain feature along the first direction. In some implementations, the first source/drain feature is disposed between a first gate structure and a second gate structure along a second direction perpendicular to the first direction and the source source/drain feature is disposed between a third gate structure and a fourth gate structure along the second direction. In some embodiments, the backside contact feature includes a first width along the second direction, the through via includes a second width along the second direction, and the second width is greater than the first width. In some instances, the through via abuts the first gate structure and the second gate structure. In some embodiments, the semiconductor structure further includes a plurality of nanostructures interfacing a sidewall of the first source/drain feature. The gate structure wraps around each of the plurality of nanostructures. In some embodiments, the semiconductor structure further includes a buffer semiconductor layer over the base fin, and a bottom isolation layer over the buffer semiconductor layer. In some embodiments, the buffer semiconductor layer includes undoped silicon, undoped germanium, or undoped silicon germanium and the bottom isolation layer includes silicon nitride.

Another aspect of the present disclosure pertains to a semiconductor structure. The semiconductor structure includes a backside dielectric layer, a backside etch stop layer (ESL) over the backside dielectric layer, a first gate structure over the backside ESL, a second gate structure over the backside ESL and aligned with the first gate structure along a first direction, a third gate structure over the backside ESL, a fourth gate structure over the backside ESL and aligned with the third gate structure along the first direction, a first source/drain feature over the backside ESL and disposed between the first gate structure and the third gate structure along a second direction perpendicular to the first direction, a second source/drain feature over the backside ESL and disposed between the second gate structure and the fourth gate structure along the second direction, a frontside source/drain contact disposed over the first source/drain feature and the second source/drain feature, a backside contact feature extending through the backside dielectric layer and the backside ESL to couple to the first source/drain feature, and a through via extending through the backside dielectric layer and the backside ESL to couple to the frontside source/drain contact. The backside contact feature interfaces the through via in the backside dielectric layer. The first gate structure includes a gate dielectric layer and a gate electrode layer over the gate dielectric layer. A dielectric constant of the gate dielectric layer is greater than a dielectric constant of the isolation feature.

In some embodiments, the backside contact feature includes a first width along the second direction. The through via includes a second width along the second direction and the second width is greater than the first width. In some implementations, the through via abuts the first gate structure and the third gate structure. In some embodiments, the semiconductor structure further includes a plurality of nanostructures interfacing a sidewall of the first source/drain feature. Te first gate structure wraps around each of the plurality of nanostructures. In some implementations, the semiconductor structure further includes a base fin between the backside ESL and the second source/drain feature, and an isolation feature including a portion extending along sidewalls of the base fin. In some embodiments, a portion of the first gate structure, the second gate structure, the third gate structure, and the fourth gate structure is disposed over and interfaces the isolation feature. In some embodiments, the frontside contact feature includes a portion that extends between the first source/drain feature and the second source/drain feature along the first direction. In some embodiments, the backside contact feature and the through via are a continuous structure.

Yet another aspect of the present disclosure pertains to a method. The method includes providing a precursor structure that includes a first source/drain feature and a second source/drain feature over a frontside source/drain contact, a first base fin over the first source/drain feature, a second base fin over the second source/drain feature, an isolation feature disposed between the first base fin and the second base fin and extending along sidewalls of the first base fin and the second base fin, and a gate isolation feature disposed between the first base fin and the second base fin, a portion of the gate isolation feature extending into the isolation feature, depositing a backside etch stop layer (ESL) over the first base fin, the second base fin, the isolation feature, and the gate isolation feature, depositing a backside dielectric layer over the backside ESL, forming a through via opening through the backside dielectric layer, the backside ESL, and the gate isolation feature to expose the frontside source/drain contact, forming a through via in the through via opening, forming a backside opening through the first base fin to expose the first source/drain feature such that a portion of the through via is exposed in the backside opening, and forming a backside contact feature in the backside opening such that the backside contact feature interfaces the through via.

In some embodiments, a bottom surface of the backside contact feature is lower than a bottom surface of the through via. In some implementations, the forming of the through via includes use of a first etch process and the forming of the backside opening includes use of a second etch process different from the first etch process. In some embodiments, the first etch process etches silicon oxide faster than it does silicon and silicon nitride and the second etch process etches silicon faster than it does silicon oxide and silicon.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a backside dielectric layer;
a backside etch stop layer (ESL) over the backside dielectric layer;
a first source/drain feature and a second source/drain feature over the backside ESL and spaced apart from one another along a first direction;
a frontside source/drain contact disposed over the first source/drain feature and the second source/drain feature;
a backside contact feature extending through the backside dielectric layer and the backside ESL to couple to the first source/drain feature;
a through via extending through the backside dielectric layer and the backside ESL to couple to the frontside source/drain contact;
a base fin between the backside ESL and the second source/drain feature; and
an isolation feature comprising a portion extending along sidewalls of the base fin,
wherein the backside contact feature interfaces the through via in the backside dielectric layer,
wherein the isolation feature comprises an oxide-based material.

2. The semiconductor structure of claim 1, wherein the frontside source/drain contact comprises a portion that extends between the first source/drain feature and the second source/drain feature along the first direction.

3. The semiconductor structure of claim 1,
wherein the first source/drain feature is disposed between a first gate structure and a second gate structure along a second direction perpendicular to the first direction,
wherein the source source/drain feature is disposed between a third gate structure and a fourth gate structure along the second direction.

4. The semiconductor structure of claim 3,
wherein the backside contact feature comprises a first width along the second direction,
wherein the through via comprises a second width along the second direction,
wherein the second width is greater than the first width.

5. The semiconductor structure of claim 3, wherein the through via abuts the first gate structure and the second gate structure.

6. The semiconductor structure of claim 3, further comprising:
a plurality of nanostructures interfacing a sidewall of the first source/drain feature,
wherein the gate structure wraps around each of the plurality of nanostructures.

7. The semiconductor structure of claim 1, further comprising:
a buffer semiconductor layer over the base fin; and
a bottom isolation layer over the buffer semiconductor layer.

8. The semiconductor structure of claim 7,
wherein the buffer semiconductor layer comprises undoped silicon, undoped germanium, or undoped silicon germanium,
wherein the bottom isolation layer comprises silicon nitride.

9. A semiconductor structure, comprising:
a backside dielectric layer;
a backside etch stop layer (ESL) over the backside dielectric layer;
a first gate structure over the backside ESL;
a second gate structure over the backside ESL and aligned with the first gate structure along a first direction;
a third gate structure over the backside ESL;
a fourth gate structure over the backside ESL and aligned with the third gate structure along the first direction;
a first source/drain feature over the backside ESL and disposed between the first gate structure and the third gate structure along a second direction perpendicular to the first direction;
a second source/drain feature over the backside ESL and disposed between the second gate structure and the fourth gate structure along the second direction;
a frontside source/drain contact disposed over the first source/drain feature and the second source/drain feature;
a backside contact feature extending through the backside dielectric layer and the backside ESL to couple to the first source/drain feature; and
a through via extending through the backside dielectric layer and the backside ESL to couple to the frontside source/drain contact,
wherein the backside contact feature interfaces the through via in the backside dielectric layer,
wherein the first gate structure comprises a gate dielectric layer and a gate electrode layer over the gate dielectric layer,
wherein a dielectric constant of the gate dielectric layer is greater than a dielectric constant of the isolation feature.

10. The semiconductor structure of claim 9,
wherein the backside contact feature comprises a first width along the second direction,
wherein the through via comprises a second width along the second direction,
wherein the second width is greater than the first width.

11. The semiconductor structure of claim 9, wherein the through via abuts the first gate structure and the third gate structure.

12. The semiconductor structure of claim 9, further comprising:
a plurality of nanostructures interfacing a sidewall of the first source/drain feature,
wherein the first gate structure wraps around each of the plurality of nanostructures.

13. The semiconductor structure of claim 9, further comprising:
a base fin between the backside ESL and the second source/drain feature; and
an isolation feature comprising a portion extending along sidewalls of the base fin.

14. The semiconductor structure of claim 13, wherein a portion of the first gate structure, the second gate structure, the third gate structure, and the fourth gate structure is disposed over and interfaces the isolation feature.

15. The semiconductor structure of claim 9, wherein the frontside contact feature comprises a portion that extends between the first source/drain feature and the second source/drain feature along the first direction.

16. The semiconductor structure of claim 9, wherein the backside contact feature and the through via are a continuous structure.

17. A method, comprising:
providing a precursor structure comprising:
a first source/drain feature and a second source/drain feature over a frontside source/drain contact,
a first base fin over the first source/drain feature,
a second base fin over the second source/drain feature,
an isolation feature disposed between the first base fin and the second base fin and extending along sidewalls of the first base fin and the second base fin, and
a gate isolation feature disposed between the first base fin and the second base fin, a portion of the gate isolation feature extending into the isolation feature;
depositing a backside etch stop layer (ESL) over the first base fin, the second base fin, the isolation feature, and the gate isolation feature;
depositing a backside dielectric layer over the backside ESL;
forming a through via opening through the backside dielectric layer, the backside ESL, and the gate isolation feature to expose the frontside source/drain contact;
forming a through via in the through via opening;
forming a backside opening through the first base fin to expose the first source/drain feature such that a portion of the through via is exposed in the backside opening; and
forming a backside contact feature in the backside opening such that the backside contact feature interfaces the through via.

18. The method of claim 17, wherein a bottom surface of the backside contact feature is lower than a bottom surface of the through via.

19. The method of claim 17,
wherein the forming of the through via comprises use of a first etch process,
wherein the forming of the backside opening comprises use of a second etch process different from the first etch process.

20. The method of claim 19,
wherein the first etch process etches silicon oxide faster than it does silicon and silicon nitride,
wherein the second etch process etches silicon faster than it does silicon oxide and silicon.
